(19) United States
(12) Patent Application Publication
(10) Pub. No.: US 2020/0022284 A1
(43) Pub. Date: Jan. 16, 2020

(54) ELECTRICAL JUNCTION BOX

(71) Applicants: AutoNetworks Technologies, Ltd., Yokkaichi, Mie (JP); Sumitomo Wiring Systems, Ltd., Yokkaichi, Mie (JP); Sumitomo Electric Industries, Ltd., Osaka-Shi (JP)

(72) Inventor: Yukinori Kita, Yokkaichi, Mie (JP)

(21) Appl. No.: 16/469,372

(22) PCT Filed: Nov. 29, 2017
(86) PCT No.: PCT/JP2017/042724

§ 371 Date: Jun. 13, 2019

(30) Foreign Application Priority Data
Dec. 14, 2016 (JP) 2016-242032

(51) Int. Cl. H05K 7/20; H01F 27/22

(52) U.S. Cl. CPC H05K 7/20509; H05K 7/20854; H02G 3/08; H01F 27/22; H05K 7/20409

(57) ABSTRACT

An electrical junction box includes a first circuit portion in which a first heat-generating component is mounted, a second circuit portion in which a second heat-generating component is mounted, a first heat dissipation member that is overlaid on the first circuit portion and dissipates heat of the first circuit portion, a second heat dissipation member that is overlaid on the second circuit portion and dissipates heat of the second circuit portion, and a support member that is made of a metal, is disposed between the first heat dissipation member and the second heat dissipation member, and supports the first heat dissipation member and the second heat dissipation member. The support member includes a heat receiving portion that is disposed between the first circuit portion and the second circuit portion and receives heat of the first heat-generating component and the second heat-generating component.

### CROSS-REFERENCE TO RELATED APPLICATIONS

This application is the U.S. national stage of PCT/JP2017/042724 filed on Nov. 29, 2017, which claims priority of Japanese Patent Application No. JP 2016-242032 filed on Dec. 14, 2016, the contents of which are incorporated herein.

### TECHNICAL FIELD

The present specification discloses technology for dissipating heat of a circuit portion.

### BACKGROUND

Technology for dissipating heat of a circuit portion from a heat dissipation member has been conventionally known. JP 2016-119798A discloses an electrical junction box that includes a circuit portion that includes a substrate on which electronic components are mounted and a bus bar, a heat dissipation member that is overlaid on a lower surface of the bus bar, and a shield cover that covers an upper surface side of the circuit portion. Heat of the electronic components mounted in the circuit portion is transferred from the bus bar to the heat dissipation member and is dissipated from the heat dissipation member to the outside.

Recently, circuits having higher density are needed in electrical junction boxes, but there is a concern that heat of a circuit having high density may not be sufficiently dissipated via a single heat dissipation member.

The technology described in the present specification was conceived based on the above circumstances, and its object is to improve the heat dissipation of an electrical junction box.

### SUMMARY

An electrical junction box described in the present specification includes a first circuit portion in which a first heat-generating component is mounted, a second circuit portion in which a second heat-generating component is mounted, a first heat dissipation member that is overlaid on the first circuit portion and dissipates heat of the first circuit portion, a second heat dissipation member that is overlaid on the second circuit portion and dissipates heat of the second circuit portion, and a support member that is made of a metal, is disposed between the first heat dissipation member and the second heat dissipation member, and supports the first heat dissipation member and the second heat dissipation member, wherein the support member includes a heat receiving portion that is disposed between the first circuit portion and the second circuit portion and receives heat of at least one of the first heat-generating component and the second heat-generating component.

According to this configuration, heat of the first heat-generating component is dissipated from the first heat dissipation member, and heat of the second heat-generating component is dissipated from the second heat dissipation member. Also, heat of at least one of the first heat-generating component and the second heat-generating component is transferred to the metal support member, and can be dissipated via the support member. Thus, heat of the heat-generating components can be not only directly dissipated from the respective heat dissipation members but also dissipated via the support member to the outside. Because heat of the heat-generating components can be dissipated via a plurality of paths, the heat dissipation can be improved.

The technology described in the present specification is preferably carried out with the following configurations.

The support member includes a partition portion that separates the first circuit portion and the second circuit portion from each other and includes the heat receiving portion, and a thickness dimension of the partition portion is increased in the heat receiving portion.

According to this configuration, it is possible to locally increase the heat capacity in the heat receiving portion and reduce the distance between the heat receiving portion and the heat-generating components, and therefore heat conductivity from the heat-generating components to the heat receiving portion can be improved.

An outer surface of the support member is exposed to the outside, and a heat dissipation fin that protrudes outward is provided on the outer surface.

According to this configuration, heat transferred to the support member can be dissipated from the heat dissipation fin to the outside.

The electrical junction box further includes a first resin frame that is fixed to the first heat dissipation member and a second resin frame that is fixed to the second heat dissipation member, wherein the first resin frame includes a first spacer portion that is disposed between the heat receiving portion and the first heat-generating component, and the second resin frame includes a second spacer portion that is disposed between the heat receiving portion and the second heat-generating component.

According to this configuration, the spacer portions made of resin are disposed between the heat receiving portion and the heat-generating components, and therefore heat of the heat-generating components can be transferred to the heat receiving portion via the spacer portions, and the occurrence of problems due to an attachment accuracy error can be suppressed by the resin frames.

At least one of the first heat-generating component and the second heat-generating component is a choke coil.

According to this configuration, heat of the choke coil that tends to have a high temperature by generating heat can be dissipated via the support member.

An attachment member that is attachable to a vehicle is fixed to the support member.

According to this configuration, heat can be dissipated via the support member and the attachment member to the outside.

### Advantageous Effects of Disclosure

According to the technology described in the present specification, the heat dissipation of the electrical junction box can be improved.

### BRIEF DESCRIPTION OF DRAWINGS

FIG. 1 is a side view of an electrical junction box of a first embodiment.

FIG. 2 is a cross-sectional view of the electrical junction box.

FIG. 3 is a plan view illustrating a state where a first circuit portion, a control circuit board, and a first resin frame are attached to a first heat dissipation member.

FIG. 4 is a cross-sectional view of an electrical junction box of a second embodiment.

### DETAILED DESCRIPTION OF PREFERRED EMBODIMENTS

### First Embodiment

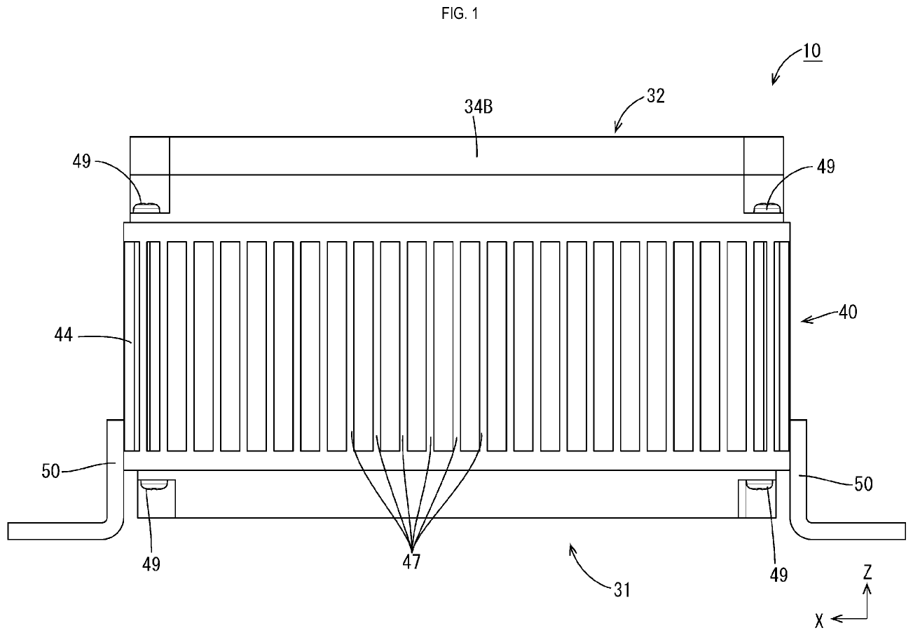

The following describes an electrical junction box 10 of the present embodiment with reference to FIGS. 1 to 3.

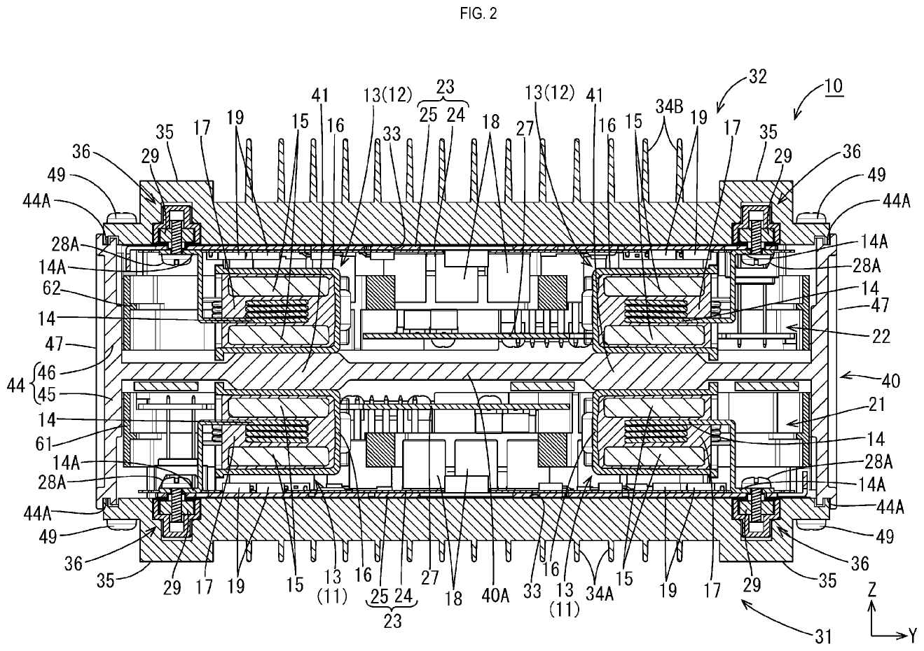

The electrical junction box 10 of the present embodiment is installed on a path from a power source such as a battery to a load in a vehicle such as an electric automobile or a hybrid automobile, for example, and can be used for a DC-DC converter, for example. In the following description, the X direction, Y direction, and Z direction in FIGS. 1 and 2 are defined as the forward direction, the rightward direction, and the upward direction, respectively.

As illustrated in FIG. 2, the electrical junction box 10 includes a first circuit portion 21, a second circuit portion 22, a first heat dissipation member 31 that is overlaid on the first circuit portion 21, a second heat dissipation member 32 that is overlaid on the second circuit portion 22, and a support member 40 that is disposed between the first heat dissipation member 31 and the second heat dissipation member 32 and supports the first heat dissipation member 31 and the second heat dissipation member 32.

### First Circuit Portion 21 and Second Circuit Portion 22

The first circuit portion 21 and the second circuit portion 22 each include a circuit board 23 and a plurality of electronic components 13, 18, and 19 that are mounted on the circuit board 23. The circuit boards 23 each include a printed circuit board 24 and a bus bar 25 overlaid on the printed circuit board 24, and are respectively bonded to the heat dissipation members 31 and 32. The printed circuit board 24 is formed by printing a conduction path made of copper foil or the like on an insulating plate made of an insulating material. The bus bar 25 is formed by punching out a metal plate material made of copper, a copper alloy, or the like according to the shape of the conduction path. The printed circuit board 24 and the bus bar 25 are, for example, bonded together using an adhesive, an adhesive sheet, or the like. A control circuit board 27 is disposed opposite to each circuit board 23.

The electronic components 13, 18, and 19 are, for example, choke coils 13, relays 19 such as field effect transistors (FETs), and capacitors 18, and terminals of the electronic components are connected to the conduction path of the printed circuit board 24 and the bus bar 25. In the present embodiment, the choke coils 13 correspond to a first heat-generating component 11 that is mounted in the first circuit portion 21 and a second heat-generating component 12 that is mounted in the second circuit portion 22. The choke coils 13 smooth out an output voltage, for example, and each include a coil main body 14, a core 15 made of a highly permeable magnetic material such as ferrite, and a coil case 16 accommodating the coil main body 14 and the core 15.

The coil main body 14 is a so-called edgewise coil made of copper or a copper alloy, for example, and has an outer surface coated with enamel. Note that this is not a limitation, and the coil main body 14 does not have to be coated with enamel. The coil main body 14 has a pair of terminal portions 14A at leading ends that are bent in a crank shape. The terminal portions 14A are each overlaid on a bus bar terminal 26 that is formed at an end portion of the bus bar 25, and as a result of the terminal portion 14A and the bus bar terminal 26 being fastened together using a bolt 28A and a nut 29 that serve as fastening members, the choke coil 13 is fixed to the circuit board 23.

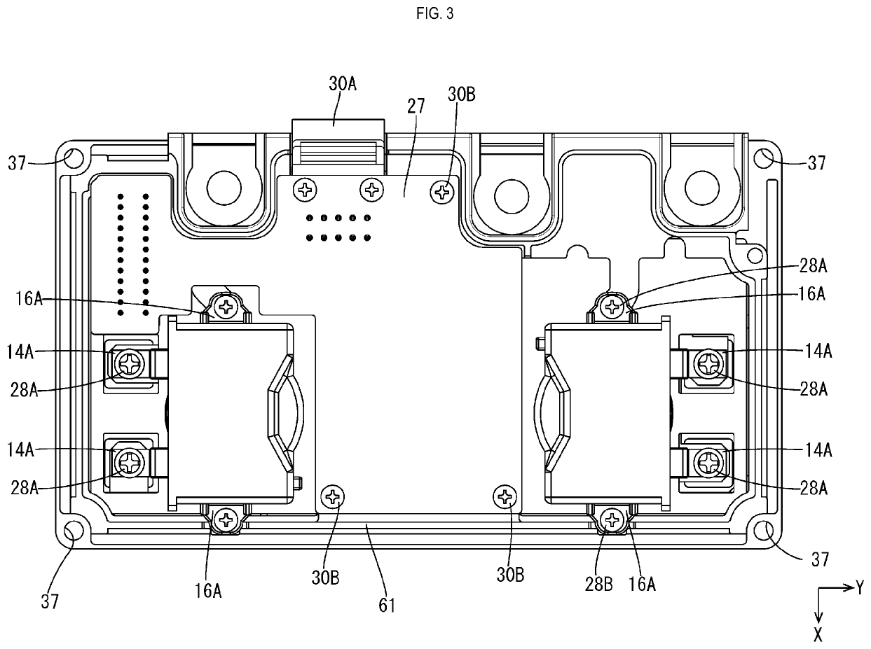

The coil case 16 is made of an insulating synthetic resin, and has the shape of a rectangular parallelepiped box that has an opening on one side. Fixing pieces 16A (see FIG. 3) that have screw holes and can be fixed using screws protrude from opposite side surfaces of the coil case 16 in a direction perpendicular to the side surfaces. As illustrated in FIG. 2, the inside of the coil case 16 is filled with a potting agent 17 in a state where the coil main body 14 and the core 15 are accommodated. The potting agent 17 fills a gap of the space within the case where the coil main body 14 and the core 15 are not disposed. The potting agent 17 used in the present embodiment is, for example, an epoxy resin, and examples of potting agents that can be used include a thermosetting resin that is injected as a liquid into the case and is solidified through heating and a cold setting resin that is cured without being heated.

The first circuit portion 21 and the second circuit portion 22 may be circuit portions that have different outputs, for example. For example, the output of the first circuit portion 21 may be 3 kW, and the output of the second circuit portion 22 may be 1 kW.

### First Heat Dissipation Member 31 and Second Heat Dissipation Member 32

The first heat dissipation member 31 and the second heat dissipation member 32 are disposed opposite to each other, and are each formed through, for example, aluminum die-casting using a highly heat-conductive metal such as aluminum, an aluminum alloy, copper, a copper alloy, or stainless steel, or a resin such as a heat-dissipating resin, for example. The first heat dissipation member 31 has a placement surface 33 on which the circuit portion 21 is placed, and a plurality of plate-shaped heat dissipation fins 34A that are arranged like comb teeth protrude from the side opposite to the placement surface 33. The second heat dissipation member 32 has a placement surface 33 on which the circuit portion 22 is placed, and a plurality of plate-shaped heat dissipation fins 34B that are arranged like comb teeth protrude from the side opposite to the placement surface 33.

The protrusion dimension of the heat dissipation fins 34A of the first heat dissipation member 31 is smaller than that of the heat dissipation fins 34B of the second heat dissipation member 32, so that the first heat dissipation member 31 side can be placed on a body of a vehicle. The placement surface 33 of each of the first heat dissipation member 31 and the second heat dissipation member 32 has a fastening portion 36 to which the bolt 28A can be screwed, and an outer surface side of the fastening portion 36 forms a protrusion 35 that protrudes outward. The fastening portion 36 is formed as a recess in the placement surface 33, and accommodates the nut 29 that is restricted from rotating. An insulating layer (not illustrated) formed of a cured adhesive or the like is layered on the placement surface 33 to insulate the heat dissipation members 31 and 32 from the respective circuit portions 21 and 22. Further, the first heat dissipation member 31 and the second heat dissipation member 32 have screw holes 37 (see FIG. 3) for fixing the first heat dissipation member 31 and the second heat dissipation member 32 to the support member 40 with screws 49.

### Support Member 40

The support member 40 is formed through, for example, aluminum die-casting using a highly heat-conductive metal such as aluminum, an aluminum alloy, copper, a copper alloy, or stainless steel, for example. The support member 40 is frame-shaped, for example, and includes a plate-shaped partition plate 40A (an example of a “partition portion”) that separates the first circuit portion 21 and the second circuit portion 22 from each other and a square tube-shaped support wall 44 that serves as a support between the first heat dissipation member 31 and the second heat dissipation member 32, as illustrated in FIG. 2.

The partition plate 40A has the shape of a substantially rectangular plate, for example, extends along the first circuit portion 21 and the second circuit portion 22, and includes a heat receiving portion 41 that receives heat of the choke coils 13. The heat receiving portion 41 has a larger thickness dimension (dimension in the vertical direction) than the other regions of the partition plate 40A, and an upper surface and a lower surface of the heat receiving portion 41 are in contact with the respective coil cases 16 of upper and lower choke coils 13. Accordingly, heat of the choke coils 13 is transferred to the heat receiving portion 41.

The support wall 44 includes a first support wall 45 that extends downward from an edge portion of the partition plate 40A and supports the first heat dissipation member 31, and a second support wall 46 that extends upward from the edge portion of the partition plate 40A and supports the second heat dissipation member 32. An outer surface of the support wall 44 is exposed to the outside, and a plurality of heat dissipation fins 47 that protrude outward are provided over the entire circumference of the support wall 44. The heat dissipation fins 47 are plate-shaped, each extending over the entire length of the support wall 44 in the vertical direction, and are arranged at constant intervals in the circumferential direction.

Annular groove portions 44A are provided at an upper end portion and a lower end portion of the support wall 44 along its entire periphery, and projections of edge portions of the first heat dissipation member 31 and the second heat dissipation member 32 can be fitted in the groove portions. Further, the upper end portion and the lower end portion of the support wall 44 include fastening portions (not illustrated) at which the support wall 44 can be fixed to the first heat dissipation member 31 and the second heat dissipation member 32 with the screws 49. As illustrated in FIG. 1, attachment members 50 made of metal are fixed to the support wall 44. The attachment members 50 are bent in an L-shape, for example, and are fixed to the body of the non-illustrated vehicle through fastening using a fastening member such as a bolt.

Note that the support member 40 can be attached to the first heat dissipation member 31 and the second heat dissipation member 32 by fixing the first heat dissipation member 31 with the first circuit portion 21 attached thereto to the first support wall 45 with screws 49 and fixing the second heat dissipation member 32 with the second circuit portion 22 attached thereto to the second support wall 46 with screws 49.

In the above-described configuration, heat transferred from the choke coil 13 or the like to the support member 40 is transferred to the first heat dissipation member 31, the second heat dissipation member 32, and the attachment member 50 that are in contact with the support member 40, and is dissipated from the first heat dissipation member 31 and the second heat dissipation member 32 to the outside as well as being transferred from the attachment member 50 to the body of the vehicle (not illustrated).

Note that, as illustrated in FIG. 2, a first resin frame 61 made of a synthetic resin is disposed on the inside of the first support wall 45 and is fixed to the first heat dissipation member 31, and a second resin frame 62 made of a synthetic resin is disposed on the inside of the second support wall 46 and is fixed to the second heat dissipation member 32. The resin frames 61 and 62 are frame-shaped and extend along inner peripheries of the respective support walls 45 and 46. The fixing pieces 16A of the choke coils 13 and the control circuit boards 27 that include connector portions 30A are fixed to the resin frames 61 and 62 with screws 28B and 30B (see FIG. 3).

The following functions and effects are achieved according to the present embodiment.

The electrical junction box 10 of the present embodiment includes the first circuit portion 21 in which the first heat-generating component 11 (choke coil 13) is mounted, the second circuit portion 22 in which the second heat-generating component 12 (choke coil 13) is mounted, the first heat dissipation member 31 that is overlaid on the first circuit portion 21 and dissipates heat of the first circuit portion 21, the second heat dissipation member 32 that is overlaid on the second circuit portion 22 and dissipates heat of the second circuit portion 22, and the metal support member 40 that is disposed between the first heat dissipation member 31 and the second heat dissipation member 32 and supports the first heat dissipation member 31 and the second heat dissipation member 32. The support member 40 includes the heat receiving portion 41 that is disposed between the first circuit portion 21 and the second circuit portion 22 and receives heat of at least one of the first heat-generating component 11 and the second heat-generating component 12.

According to the present embodiment, heat generated by the first heat-generating component 11 is dissipated from the first heat dissipation member 31, and heat generated by the second heat-generating component 12 is dissipated from the second heat dissipation member 32. Also, heat generated by the first heat-generating component 11 and heat generated by the second heat-generating component 12 are transferred to the heat receiving portion 41 of the metal support member 40, and can be dissipated via the support member 40. Thus, heat of the heat-generating components 11 and 12 can be not only directly dissipated from the respective heat dissipation members 31 and 32 but also dissipated via the support member 40 to the outside. Because heat of the heat-generating components 11 and 12 can be efficiently dissipated via a plurality of paths, the heat dissipation can be improved.

Further, the support member 40 includes the partition plate 40A (partition portion) that separates the first circuit portion 21 and the second circuit portion 22 from each other and includes the heat receiving portion 41, and the thickness dimension of the partition plate 40A is increased in the heat receiving portion 41.

According to this configuration, it is possible to locally increase the heat capacity in the heat receiving portion 41 and reduce the distance between the heat receiving portion 41 and the heat-generating components 11 and 12, and therefore heat conductivity from the heat-generating components 11 and 12 to the heat receiving portion 41 can be improved.

Further, the outer surface of the support member 40 is exposed to the outside, and the outwardly protruding heat dissipation fins 47 are provided on the outer surface.

According to this configuration, heat transferred to the support member 40 can be dissipated from the heat dissipation fins 47 to the outside.

Further, the heat-generating components 11 and 12 are the choke coils 13.

According to this configuration, heat of the choke coils 13 that tend to have a high temperature by generating heat can be dissipated via the support member 40.

Further, the attachment member 50 that is attachable to the vehicle is fixed to the support member 40.

According to this configuration, heat can be dissipated via the support member 40 and the attachment member 50 to the outside.

### Second Embodiment

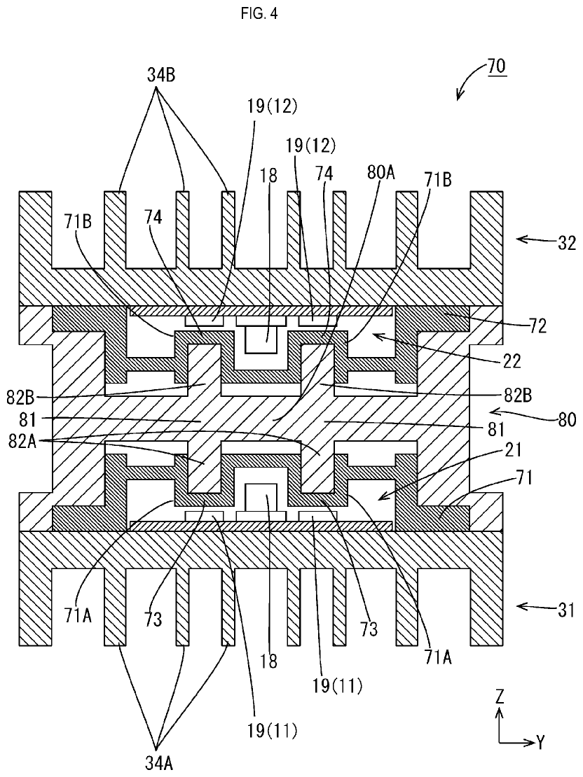

The following describes a second embodiment with reference to FIG. 4. In an electrical junction box 70 of the second embodiment, heat of heat-generating components 11 and 12 is transferred to a support member 80 via resin frames 71 and 72. In the following description, the same structures as those in the first embodiment are denoted with the same reference signs as those used in the first embodiment, and their further description is omitted.

As illustrated in FIG. 4, the electrical junction box 70 includes a first circuit portion 21, a second circuit portion 22, a first heat dissipation member 31, a second heat dissipation member 32, a support member 80 that is made of metal, is disposed between the first heat dissipation member 31 and the second heat dissipation member 32, and supports the first heat dissipation member 31 and the second heat dissipation member 32, a first resin frame 71 that is made of a synthetic resin and is fixed to the first heat dissipation member 31, and a second resin frame 72 that is made of a synthetic resin and is fixed to the second heat dissipation member 32.

The support member 80 includes a plate-shaped partition plate 80A (an example of a “partition portion”) that separates the first circuit portion 21 and the second circuit portion 22 from each other. The partition plate 80A includes a heat receiving portion 81 that receives heat of relays 19, and the heat receiving portion 81 includes, at positions corresponding to the relays 19, a first protrusion 82A that protrudes toward a relay 19 of the first circuit portion 21 and a second protrusion 82B that protrudes toward a relay 19 of the second circuit portion 22. In the second embodiment, the relays 19 correspond to the first heat-generating component 11 and the second heat-generating component 12.

The first resin frame 71 has a fitting recess 71A that is fitted on the first protrusion 82A, and the second resin frame 72 has a fitting recess 71B that is fitted on the second protrusion 82B. A bottom surface portion of the fitting recess 71A serves as a first spacer portion 73 that is disposed between the first protrusion 82A and the first heat-generating component 11, and a bottom surface portion of the fitting recess 71B serves as a second spacer portion 74 that is disposed between the second protrusion 82B and the second heat-generating component 12. In the present embodiment, there are gaps between the spacer portions 73 and 74 and the relays 19, but this is not a limitation, and the spacer portions 73 and 74 may be in contact with the relays 19.

According to the second embodiment, the spacer portions 73 and 74 made of resin are interposed between the heat receiving portion 81 and the heat-generating components 11 and 12, and therefore heat of the heat-generating components 11 and 12 can be transferred to the heat receiving portion 81 via the spacer portions 73 and 74, and the occurrence of problems due to an attachment accuracy error can be suppressed by the resin frames 71 and 72.

### Other Embodiments

The technology described in the present specification is not limited to the embodiments described above with reference to the drawings, and the following embodiments are also included in the technical scope of the technology described in the present specification, for example.

In the above-described embodiments, the thickness dimensions of the partition plates 40A and 80A are increased in the heat receiving portions 41 and 81, but this is not a limitation. For example, the partition plates 40A and 80A may each have a constant thickness.

The choke coils 13 are each configured such that the coil case 16 is in contact with the heat receiving portion 41, but this is not a limitation, and a part of the choke coil 13 other than the coil case 16 may be in contact with the heat receiving portion 41. Further, the choke coils 13 need not be in contact with the heat receiving portion 41, and a gap that allows for heat transfer from the heat-generating components 11 and 12 to the heat receiving portion may be formed between the choke coils 13 and the heat receiving portion.

The heat receiving portion 41 is configured to receive heat of both the first heat-generating component 11 and the second heat-generating component 12, but this is not a limitation, and the heat receiving portion 41 may be configured to receive heat of only one of the first heat-generating component 11 and the second heat-generating component 12.

In the first embodiment, the heat-generating components 11 and 12 are the choke coils 13, but this is not a limitation, and the heat-generating components 11 and 12 may be relays 19, for example. In the second embodiment, the heat-generating components 11 and 12 are the relays 19, but this is not a limitation, and the heat-generating components 11 and 12 may be choke coils 13, for example.

In the first embodiment, the inside of the coil case 16 is filled with the potting agent 17, but this is not a limitation. For example, a space within the coil case 16 where the coil main body 14 and the core 15 are not disposed may be filled with air. Further, the coil case 16 may be omitted and the coil main body 14 and the core 15 may be exposed, for example.

In the above-described embodiments, each of the support members 40 and 80 is made of metal, but this is not a limitation. For example, the support member may be made of resin that is capable of dissipating heat. Alternatively, the support member may include a metal member disposed within resin. For example, the support member may include metal (for example, a metal plate) that is disposed within the partition plate 40A made of resin or is partially exposed from the partition plate 40A made of resin. A support member including metal can be formed through, for example, insertion molding by disposing a metal member within a mold and filling the mold with resin.

1. An electrical junction box comprising:
a first circuit portion in which a first heat-generating component is mounted;
a second circuit portion in which a second heat-generating component is mounted;
a first heat dissipation member that is overlaid on the first circuit portion and dissipates heat of the first circuit portion;
a second heat dissipation member that is overlaid on the second circuit portion and dissipates heat of the second circuit portion; and
a support member that is made of a metal, is disposed between the first heat dissipation member and the second heat dissipation member, and supports the first heat dissipation member and the second heat dissipation member,
wherein the support member includes a heat receiving portion that is disposed between the first circuit portion and the second circuit portion and receives heat of at least one of the first heat-generating component and the second heat-generating component.

2. The electrical junction box according to claim 1,
wherein the support member includes a partition portion that separates the first circuit portion and the second circuit portion from each other and includes the heat receiving portion, and a thickness dimension of the partition portion is increased in the heat receiving portion.

3. The electrical junction box according to claim 1,
wherein an outer surface of the support member is exposed to the outside, and a heat dissipation fin that protrudes outward is provided on the outer surface.

4. The electrical junction box according to claim 1, further comprising:
a first resin frame that is fixed to the first heat dissipation member and a second resin frame that is fixed to the second heat dissipation member,
wherein the first resin frame includes a first spacer portion that is disposed between the heat receiving portion and the first heat-generating component, and the second resin frame includes a second spacer portion that is disposed between the heat receiving portion and the second heat-generating component.

5. The electrical junction box according to claim 1,
wherein at least one of the first heat-generating component and the second heat-generating component is a choke coil.

6. The electrical junction box according to claim 1,
wherein an attachment member that is attachable to a vehicle is fixed to the support member.

7. The electrical junction box according to claim 2,
wherein an outer surface of the support member is exposed to the outside, and a heat dissipation fin that protrudes outward is provided on the outer surface.

8. The electrical junction box according to claim 2, further comprising:
a first resin frame that is fixed to the first heat dissipation member and a second resin frame that is fixed to the second heat dissipation member,
wherein the first resin frame includes a first spacer portion that is disposed between the heat receiving portion and the first heat-generating component, and the second resin frame includes a second spacer portion that is disposed between the heat receiving portion and the second heat-generating component.

9. The electrical junction box according to claim 3, further comprising:
a first resin frame that is fixed to the first heat dissipation member and a second resin frame that is fixed to the second heat dissipation member,
wherein the first resin frame includes a first spacer portion that is disposed between the heat receiving portion and the first heat-generating component, and the second resin frame includes a second spacer portion that is disposed between the heat receiving portion and the second heat-generating component.

10. The electrical junction box according to claim 2, wherein at least one of the first heat-generating component and the second heat-generating component is a choke coil.

11. The electrical junction box according to claim 3, wherein at least one of the first heat-generating component and the second heat-generating component is a choke coil.

12. The electrical junction box according to claim 4, wherein at least one of the first heat-generating component and the second heat-generating component is a choke coil.

13. The electrical junction box according to claim 2, wherein an attachment member that is attachable to a vehicle is fixed to the support member.

14. The electrical junction box according to claim 3, wherein an attachment member that is attachable to a vehicle is fixed to the support member.

15. The electrical junction box according to claim 4, wherein an attachment member that is attachable to a vehicle is fixed to the support member.

16. The electrical junction box according to claim 5, wherein an attachment member that is attachable to a vehicle is fixed to the support member.
